(19) United States
(12) Patent Application Publication
(10) Pub. No.: US 2014/0022021 A1
(43) Pub. Date: Jan. 23, 2014

(54) POWER AMPLIFIER

(71) Applicant: Murata Manufacturing Co., Ltd., Nagaokakyo-shi (JP)

(72) Inventor: Keiji KUSACHI, Nagaokakyo-shi (JP)

(21) Appl. No.: 13/924,719

(22) Filed: Jun. 24, 2013

(30) Foreign Application Priority Data
Jul. 17, 2012 (JP) 2012-158290

(51) Int. Cl. H03F 3/21

(52) U.S. Cl. CPC H03F 3/21
USPC 330/296

(57) ABSTRACT

A power amplifier includes an amplifying element, a bias circuit, a common power supply terminal, and a resistor or an inductor. The bias circuit is connected to the amplifying element and supplies a bias voltage to an input terminal of the amplifying element. The bias circuit and an output bias terminal of the amplifying element are connected to the common power supply terminal. The resistor or the inductor is connected in series between the bias circuit and the common power supply terminal.

### BACKGROUND OF THE INVENTION

1. Field of the Invention

The present invention relates to a power amplifier, and more particularly, to a power amplifier including a feature in a circuit that supplies bias voltage.

2. Description of the Related Art

Power amplifiers are built in a communication apparatus or the like and are used for amplifying transmission signals. Furthermore, power amplifiers are commercialized as IC packages. For example, power amplifiers described in Japanese Unexamined Patent Application Publication Nos. 7-154159 and 2005-341447 and Japanese Unexamined Patent Application Publication No. 2004-516737 have been available.

A power amplifier described in Japanese Unexamined Patent Application Publication No. 7-154159 includes a bypass capacitor, a choke coil, and a field-effect transistor (FET). A drain terminal of the FET is connected to an output-side matching circuit and one end of the choke coil. The other end of the choke coil is connected to a power supply terminal. The connection point between the choke coil and the power supply terminal is connected through a bypass capacitor to the ground. In the power amplifier, bias voltage applied to the drain terminal is supplied without voltage drop by the output-side matching circuit.

A power amplifier described in Japanese Unexamined Patent Application Publication No. 2004-516737 includes an FET that is cascade-connected to a capacitor and a bonding wire. A gate terminal of a specific FET is connected through the capacitor and the bonding wire to the ground. In the power amplifier, by preventing output of the FET from being fed back to the gate, oscillation can be suppressed.

A power amplifier described in Japanese Unexamined Patent Application Publication No. 2005-341447 includes a bias circuit, an impedance control circuit, and an FET. The impedance control circuit includes a capacitor, an inductor, and a resistor that are connected in series. A drain terminal is connected through the bias circuit to a power supply terminal. The connection point between the bias circuit and the power supply terminal is connected through the impedance control circuit to the ground. The power amplifier achieves matching in a wide frequency band by the impedance control circuit.

Furthermore, for example, a power amplifier illustrated in FIG. 9 has also been available. FIG. 9 is a circuit diagram illustrating an example of an existing power amplifier.

A power amplifier 1P includes an IC chip 2 and is connected through external components to an external power supply terminal P8. The power amplifier 1P includes amplifying elements 11 and 12, a bias circuit 13, an input terminal P1, an output terminal P2, power supply terminals P61P, P62P, and P7, and a control terminal P11.

The amplifying element 11 is connected to the input terminal P1. The amplifying element 12 is connected to the output terminal P2. The amplifying elements 11 and 12 are cascade-connected. Bias terminals P3 of the amplifying elements 11 and 12 are connected to an output terminal of the bias circuit 13. An output bias terminal P4 of the amplifying element 11 is connected through a bonding wire 22P to the power supply terminal P62P. An output bias terminal P5 of the amplifying element 12 is connected through a bonding wire 23 to the power supply terminal P7.

A power supply terminal of the bias circuit 13 is connected to the power supply terminal P61P through a bonding wire 21P. An input terminal of the bias circuit 13 is connected to the control terminal P11.

The power supply terminal P61P is connected to the external power supply terminal P8. The power supply terminal P62P is connected to a connection point 31P between the power supply terminal P61P and the external power supply terminal P8. The power supply terminal P7 is connected through a choke coil L1 to a connection point 32P between the connection point 31P and the external power supply terminal P8. The connection point between the power supply terminal P61P and the connection point 31P is connected through a bypass capacitor C1P to the ground. The connection point between the power supply terminal P62P and the connection point 31P is connected through a bypass capacitor C2P to the ground. The connection point between one end of the coil L1 and the connection point 32P is connected through a bypass capacitor C3 to the ground. The bypass capacitors C1P, C2P, and C3 and the choke coil L1 are external components connected to the power amplifier 1P.

The bias voltage of the amplifying elements 11 and 12 is supplied from the external power supply terminal P8. The input bias voltage of the amplifying elements 11 and 12 is supplied via the power supply terminal P61P, the bonding wire 21P, and the bias circuit 13. The output bias voltage of the amplifying element 11 is supplied via the power supply terminal P62P and the bonding wire 22P. The output bias voltage of the amplifying element 12 in the final stage is supplied via the choke coil L1, the power supply terminal P7, and the bonding wire 23.

The bias circuit 13 supplies a specific input bias voltage to the amplifying elements 11 and 12 in accordance with signals from the control terminal P11 and a detection circuit, which is not illustrated. Power is supplied to the bias circuit 13 from a power supply terminal connected to the external power supply terminal P8.

As illustrated in FIG. 9, the power supply terminal P61P for input bias voltage and the power supply terminal P62P for output bias voltage are provided separately. If the power supply terminals P61P and P62P are integrated to be a common power supply terminal, the size of the power amplifier 1P can be reduced. However, in the case where the common power supply terminal is used, since output of the amplifying element 11 is fed back through the common power supply terminal to the input of the amplifying element 11, oscillation or the like may occur in the power amplifier 1P.

### SUMMARY OF THE INVENTION

Accordingly, preferred embodiments of the present invention significantly reduce the size of a power amplifier while maintaining the characteristics of the power amplifier.

A power amplifier according to a preferred embodiment of the present invention includes an amplifying element, a bias circuit, a common power supply terminal, and a resistor or an inductor. The bias circuit is connected to the amplifying element and supplies a bias voltage to an input terminal of the amplifying element. The bias circuit and an output bias terminal of the amplifying element are connected to the common power supply terminal. The resistor or the inductor is connected in series between the bias circuit and the common power supply terminal.

With this configuration, compared to the case where input bias voltage and output bias voltage are supplied via individual power supply terminals separately provided in a power amplifier, the size of the power amplifier can be reduced. The resistance or the inductor prevents the power gain of the power amplifier from being reduced. Thus, the size of the power amplifier can be reduced while the power gain of the power amplifier is maintained.

The power amplifier preferably includes a capacitor. One end of the capacitor is connected to a connection point between one end of the resistor or the inductor and the bias circuit. The other end of the capacitor is connected to the ground. With this configuration, output from the amplifying circuit is prevented from being fed back to input of the amplifying element, and the power amplifier is prevented from oscillating.

According to various preferred embodiments of the present invention, the size of the power amplifier is significantly reduced while maintaining the power gain of the power amplifier.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a circuit diagram of a power amplifier according to a first preferred embodiment of the present invention.

FIG. 2 is a circuit diagram illustrating a principal portion of a power amplifier.

FIG. 3 is a characteristic diagram illustrating the power gain of power amplifiers relative to frequency.

FIG. 4 is a characteristic diagram illustrating the power gain of power amplifiers relative to frequency.

FIG. 5 is a characteristic diagram illustrating the power gain of a power amplifier relative to the resistance of a resistor.

FIG. 6 is a characteristic diagram illustrating the output bias current of the power amplifier relative to the resistance of the resistor.

FIG. 7 is a circuit diagram illustrating a principal portion of a power amplifier according to a second preferred embodiment of the present invention.

FIG. 8 is a characteristic diagram illustrating the power gain of the power amplifier relative to the inductance of an inductor.

FIG. 9 is a circuit diagram illustrating an example of an existing power amplifier.

### DETAILED DESCRIPTION OF THE PREFERRED EMBODIMENTS

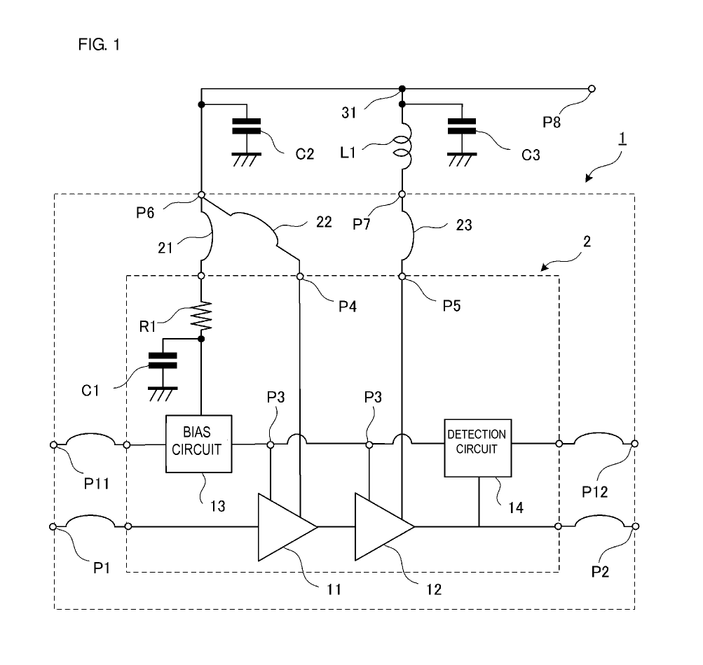

A power amplifier according to a first preferred embodiment of the present invention will be explained. FIG. 1 is a circuit diagram of the power amplifier according to the first preferred embodiment.

A power amplifier 1 includes an IC chip 2 and is connected through external components to an external power supply terminal P8. The power amplifier 1 is, for example, an IC package having a size of about 1.6 mm.

The power amplifier 1 includes amplifying elements 11 and 12, a bias circuit 13, a detection circuit 14, a bypass capacitor C1, a resistor R1, an input terminal P1, an output terminal P2, a common power supply terminal P6, a power supply terminal P7, a control terminal P11, and a reference terminal P12. The bypass capacitor C1 corresponds to a capacitor according to a preferred embodiment of the present invention.

The amplifying element 11 is connected to the input terminal P1. The amplifying element 12 is connected to the output terminal P2. The amplifying elements 11 and 12 are cascade-connected. The amplifying elements 11 and 12 are, for example, FETs, bipolar transistors, or the like.

An input terminal of the bias circuit 13 is connected to the control terminal P11. An output terminal of the bias circuit 13 is connected to the detection circuit 14. A power supply terminal of the bias circuit 13 is connected to one end of the resistor R1. The connection point between the bias circuit and the detection circuit 14 is connected to input bias terminals P3 of the amplifying elements 11 and 12. The connection point between the bias circuit 13 and the resistor R1 is connected through the bypass capacitor C1 to the ground. The bypass capacitor C1 preferably is, for example, a metal-insulator-metal capacitor (MIMC) having a capacitance of about 5 pF. The resistor R1 preferably has, for example, a value between about 100Ω and about 1500Ω.

The detection circuit 14 is connected to the connection point between the amplifying element 12 and the output terminal P2. The detection circuit 14 is connected to the reference terminal P12.

The other end of the resistor R1 is connected through a bonding wire 21 to the common power supply terminal P6. An output bias terminal P4 of the amplifying element 11 is connected through a bonding wire 22 to the common power supply terminal P6. An output bias terminal P5 of the amplifying element 12 is connected through a bonding wire 23 to the power supply terminal P7. For example, the bonding wires each preferably have a length of about 0.5 mm and a diameter of about 25 μm. In this case, the inductance of each of the bonding wires preferably is about 0.5 nH, for example.

In the case where the amplifying elements 11 and 12 are bipolar transistors, the output bias terminals correspond to collector terminals. Furthermore, the input bias terminals are connected to the base terminals and supply bias voltage to the base terminals.

The input terminal P1, the output terminal P2, the common power supply terminal P6, the power supply terminal P7, the control terminal P11, and the reference terminal P12 are located near the IC chip 2 and are connected through bonding wires to specific terminals located in the IC chip 2.

The common power supply terminal P6 is connected to the external power supply terminal P8. The power supply terminal P7 is connected through a choke coil L1 to a connection point 31 between the common power supply terminal P6 and the external power supply terminal P8. One end of a bypass capacitor C2 is connected between the common power supply terminal P6 and the connection point 31. The other end of the bypass capacitor C2 is connected to the ground. One end of a bypass capacitor C3 is connected between the choke coil L1 and the connection point 31. The other end of the bypass capacitor C3 is connected to the ground. The bypass capacitors C2 and C3 and the choke coil L1 are external components connected to the power amplifier 1. For example, the bypass capacitors C2 and C3 each preferably have a capacitance of about 100 pF.

The bias voltage of the amplifying elements 11 and 12 is supplied from the external power supply terminal P8. The input bias voltage of the amplifying elements 11 and 12 is supplied via the common power supply terminal P6, the bonding wire 21, the resistor R1, and the bias circuit 13. The output bias voltage of the amplifying element 11 is supplied via the common power supply terminal P6 and the bonding wire 22. The output bias voltage of the amplifying element 12 in the final stage is supplied via the choke coil L1, the power supply terminal P7, and the bonding wire 23.

The bypass capacitors C1, C2, and C3 prevent a high-frequency signal from being supplied to a direct-current power supply. That is, the bypass capacitors C1, C2, and C3 prevent the output of the amplifying elements 11 and 12 from being fed back to the input of the amplifying elements 11 and 12. Thus, oscillation, power gain ripple, and the like of the power amplifier 1 can be prevented, and the error-vector-magnitude (EVM) characteristics can be improved.

The bias circuit 13 supplies a specific input bias voltage to the amplifying elements 11 and 12 in accordance with signals from the control terminal P11 and the detection circuit 14. Power is supplied to the bias circuit 13 from a power supply terminal connected to the external power supply terminal P8. The detection circuit 14 compares an output signal with a signal from the reference terminal P12, and sends a specific signal to the bias circuit 13.

A signal input from the input terminal P1 is amplified by the amplifying elements 11 and 12 and is output to the output terminal P2. For example, input and output signals each preferably have a frequency within a range between about 2.4 GHz and about 2.5 GHz.

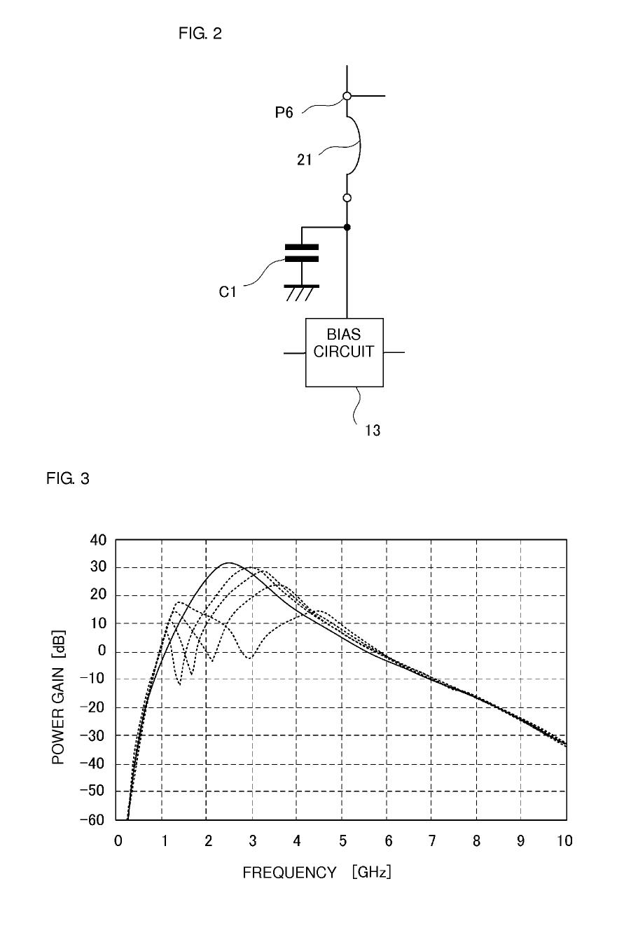

In order to explain the role of the resistor R1, the power amplifier 1 is compared with a power amplifier 1C. FIG. 2 is a circuit diagram illustrating a principal portion of the power amplifier 1C. The configuration of the power amplifier 1C is similar to the configuration of the power amplifier 1 with the exception that the power amplifier 1C does not include the resistor R1 provided in the power amplifier 1.

The bias circuit 13 is connected through the bonding wire 21 to the common power supply terminal P6. The output bias terminal P4 of the amplifying element 11 is connected through the bonding wire 22 to the common power supply terminal P6. The connection point between the bias circuit 13 and the common power supply terminal P6 is connected through the bypass capacitor C1 to the ground.

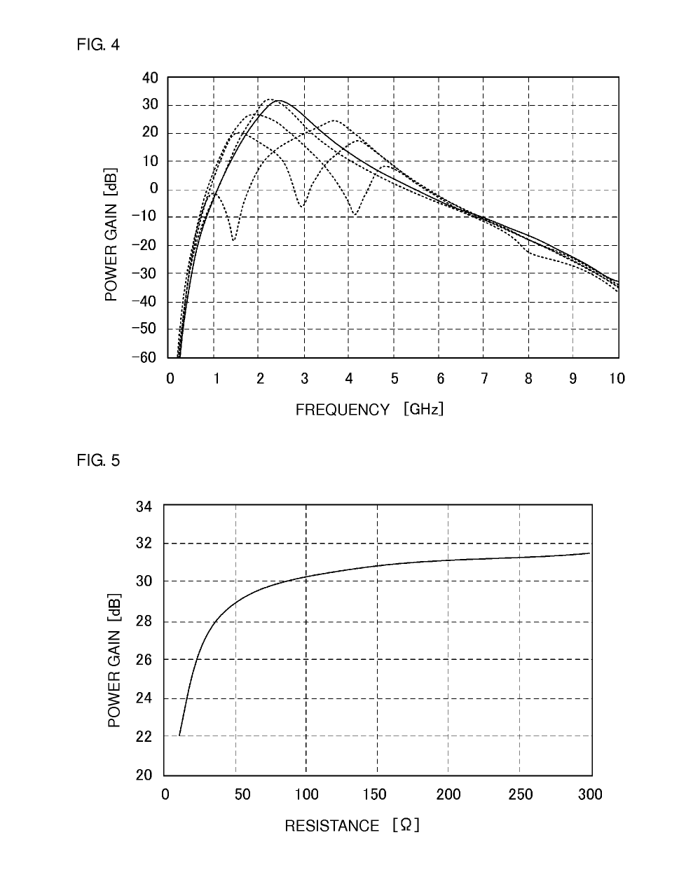

FIGS. 3 and 4 illustrate power gain of the power amplifiers 1 and 1C with respect to frequency. In FIGS. 3 and 4, the vertical axis represents power gain and the horizontal axis represents the frequency of an input/output signal. The solid lines in FIGS. 3 and 4 represent the power gain of the power amplifier 1. The dotted lines in FIGS. 3 and 4 represent the power gain of the power amplifier 1C. Referring to FIG. 3, the length of a bonding wire in the power amplifier 1C preferably is changed from about 100 μm to about 1000 μm, for example. Referring to FIG. 4, the capacitance of the bypass capacitor C1 in the power amplifier 1C is preferably changed from about 1 pF to about 30 pF, for example.

As represented by the dotted lines in FIG. 3, the power gain of the power amplifier 1C is reduced in a frequency band between about 1.5 GHz and about 3 GHz. The reduction in the power gain is observed also when the length of a bonding wire is changed.

As represented by the dotted lines in FIG. 4, the power gain of the power amplifier 1C is reduced in a frequency band between about 1.5 GHz and about 6 GHz. The reduction in the power gain is observed also when the capacitance is changed except for the case where the capacitance is near about 1 pF. When the capacitance is near about 1 pF, the bypass capacitor C1 cannot fully prevent a high-frequency signal from flowing to a direct-current power supply.

Thus, even if the length of a bonding wire or the capacitance is changed, a reduction in the power gain of the power amplifier 1C cannot be avoided in a use band (for example, about 2.4 GHz to about 2.5 GHz).

In contrast, as represented by the solid lines in FIGS. 3 and 4, the power gain of the power amplifier 1 is not reduced in a use band. Thus, the resistor R1 has a function of preventing a reduction of the power gain of the power amplifier 1.

The above-mentioned result is caused by the reason described below. In the case where the bonding wire 21 and the bypass capacitor C1 are connected in series as in the power amplifier 1C, the inductance of the bonding wire 21 and the capacitance of the bypass capacitor C1 operate as a series resonant circuit. Thus, in the case of the power amplifier 1C, due to resonance of the series resonance circuit, the power gain is reduced in a specific frequency range. Meanwhile, in the case of the power amplifier 1, the resistor R1 is connected between the bonding wire 21 and the bypass capacitor C1. Accordingly, resonance of the series circuit including the bonding wire 21 and the bypass capacitor C1 can be suppressed. Thus, a reduction of the power gain is negligible.

FIG. 5 illustrates the power gain of the power amplifier 1 relative to the resistance of the resistor R1. The frequency of an input/output signal preferably is about 2.4 GHz, for example. In the case where the resistance preferably is less than about 100Ω, as the resistance increases, the power gain increases. In the case where the resistance is equal to or more than about 100Ω, the power gain is maintained substantially constant, irrespective of resistance.

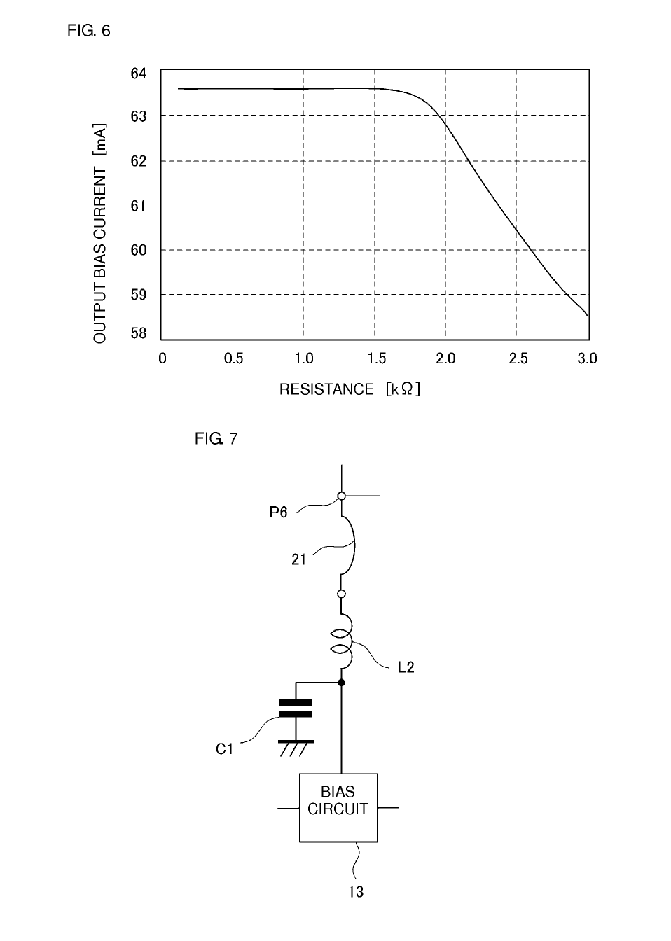

FIG. 6 illustrates an output bias current (power supply current) of the power amplifier 1 relative to the resistance of the resistor R1. In the case where the resistance is less than about 1500Ω, the output bias current is maintained substantially constant, irrespective of resistance. In the case where the resistance is equal to or more than about 1500Ω, the power gain decreases as the resistance increases.

Thus, by setting the resistance of the resistor R1 within a range between about 100Ω and about 1500Ω, reduction of the power gain and the output bias current can be prevented.

According to the first preferred embodiment, compared to the case where input bias voltage and output bias voltage are supplied via individual power supply terminals separately formed in the power amplifier 1, the size of the power amplifier 1 can be significantly reduced. The bypass capacitor C1 prevents the output of the amplifying element 11 from being fed back to the input of the bypass capacitor C1 and prevents the power amplifier from oscillating or the like. The resistor R1 prevents the power gain and the output bias voltage from being reduced. Thus, the size of the power amplifier 1 can be reduced while maintaining the characteristics of the power amplifier 1. Furthermore, by reducing the number of terminals, the number of external components can be reduced. In order to achieve a required power gain, three or more amplifying elements may be cascade-connected.

A power amplifier according to a second preferred embodiment of the present invention will now be explained. FIG. 7 is a circuit diagram illustrating a principal portion of the power amplifier according to the second preferred embodiment. A power amplifier 1A according to the second preferred embodiment includes an inductor L2, instead of the resistor R1 provided in the first preferred embodiment. The other features of the configuration of the power amplifier 1A according to the second preferred embodiment are similar to those of the configuration of the power amplifier 1 according to the first preferred embodiment. Hereinafter, points different from the first preferred embodiment will be explained.

The bias circuit 13 is connected to one end of the inductor L2. The connection point between the bias circuit 13 and the inductor L2 is connected through the bypass capacitor C1 to the ground. The other end of the inductor L2 is connected through the bonding wire 21 to the common power supply terminal P6. The output bias terminal P4 of the amplifying element 11 is connected through the bonding wire 22 to the common power supply terminal P6.

By connecting the inductor L2 between the bonding wire 21 and the bypass capacitor C1, the inductance of the inductor L2 can be added to the inductance component of the series resonant circuit including the inductance of the bonding wire 21 and the capacitance of the bypass capacitor C1. Accordingly, the resonant frequency can be moved outside a use band. Thus, reduction of the power gain of the power amplifier 1A can be prevented.

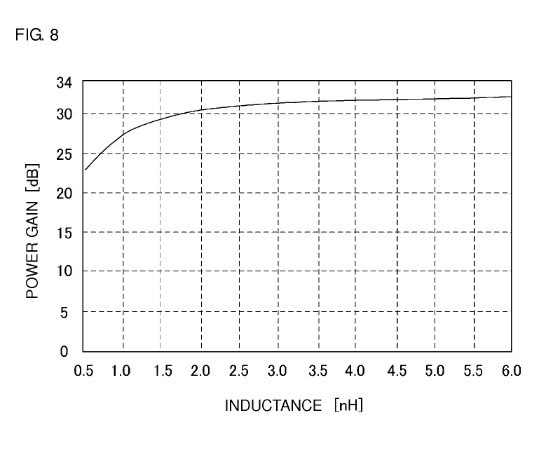

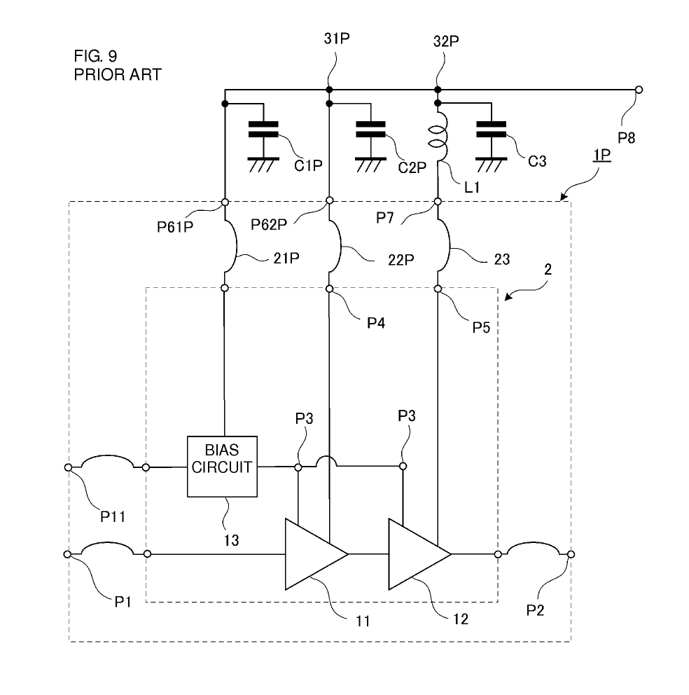

FIG. 8 illustrates power gain of the power amplifier 1A relative to the inductance of the inductor L2. The frequency of an input/output frequency preferably is about 2.45 GHz, for example. In the case where the inductance is less than about 3.0 nH, as the inductance increases, the power gain increases. In the case where the inductance is equal to or more than about 3.0 nH, the power gain is maintained substantially constant, irrespective of inductance.

Thus, by setting the inductance of the inductor L2 to about 3.0 nH or more, reduction of power gain can be prevented.

According to the second preferred embodiment, the size of the power amplifier 1A can be reduced while the characteristics of the power amplifier 1A are maintained. Furthermore, by reducing the number of terminals, the number of external components can be reduced.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A power amplifier comprising:
an amplifying element;
a bias circuit that is connected to the amplifying element and that supplies a bias voltage to an input terminal of the amplifying element;
a common power supply terminal to which the bias circuit and an output bias terminal of the amplifying element are connected; and
a resistor or an inductor that is connected in series between the bias circuit and the common power supply terminal.

2. The power amplifier according to claim 1, further comprising a capacitor, one end of the capacitor being connected to a connection point between one end of the resistor or the inductor and the bias circuit, the other end of the capacitor being connected to ground.

3. The power amplifier according to claim 1, wherein the common power supply terminal is connected through a bonding wire to the resistor or the inductor.

4. The power amplifier according to claim 1, wherein a value of resistance or inductance is within a range in which a power gain and an output bias current relative to the value of the resistance or the inductance are maintained substantially constant.

5. The power amplifier according to claim 1, further comprising a power supply terminal that is different from the common power supply terminal; wherein
the amplifying element includes a plurality of amplifying elements that are cascade-connected to each other; and
the output bias terminal of the amplifying element in a final stage is connected to the power supply terminal, instead of being connected to the common power supply terminal.

6. The power amplifier according to claim 2, wherein the capacitor is a bypass capacitor.

7. The power amplifier according to claim 5, wherein the plurality of amplifying elements are FETs or bipolar transistors.

8. The power amplifier according to claim 1, further comprising a detection circuit connected to a connection point between the amplifying element and an output terminal.

9. The power amplifier according to claim 8, wherein the detection circuit is connected to a reference terminal.

10. The power amplifier according to claim 1, further comprising an IC chip arranged adjacent to the input terminal, an output terminal, the common power supply terminal, a power supply terminal, a control terminal and a reference terminal.

11. The power amplifier according to claim 1, wherein the common power supply terminal is connected to an external power supply terminal, the power amplifier further comprising a power supply terminal that is connected through a choke coil to a connection point between the common power supply terminal and the external power supply terminal.

12. The power amplifier according to claim 1, wherein bypass capacitors are arranged to prevent an output of the amplifying element from being fed back to an input of the amplifying element.

13. The power amplifier according to claim 1, further comprising a detection circuit arranged to compare an output signal with a signal from a reference terminal and to send a signal to the bias circuit.

14. The power amplifier according to claim 6, wherein a capacitance of the capacitor is about 5 pF.

15. The power amplifier according to claim 1, wherein a resistance of the resistor is about 100Ω to about 1500Ω.

16. The power amplifier according to claim 1, wherein an inductance of the inductor is about 3.0 nH or more.
